(19) United States
(12) Patent Application Publication
(10) Pub. No.: US 2025/0095728 A1
(43) Pub. Date: Mar. 20, 2025

(54) COMPUTING APPARATUS AND ROBUSTNESS PROCESSING METHOD THEREFOR

(71) Applicant: TSINGHUA UNIVERSITY, Beijing (CN)

(72) Inventors: Bin GAO, Beijing (CN); Peng YAO, Beijing (CN); Huaqiang WU, Beijing (CN); Jianshi TANG, Beijing (CN); He QIAN, Beijing (CN)

(73) Assignee: TSINGHUA UNIVERSITY, Beijing (CN)

(21) Appl. No.: 18/580,872

(22) PCT Filed: Dec. 13, 2021
(86) PCT No.: PCT/CN2021/137445

§ 371 Date: Jan. 19, 2024

(30) Foreign Application Priority Data
Jul. 21, 2021 (CN) 202110823231.2

(51) Int. Cl. G11C 13/00

(52) U.S. Cl. CPC G11C 13/004; G11C 13/0069

(57) ABSTRACT

A computing apparatus and a robustness processing method thereof. The robustness processing method includes: based on model parameters of a target algorithm model, obtaining a mapping relationship between the model parameters and the first computing memristor array; based on an influence factor that determines a critical weight device, determining a way to obtain a weight criticality of the plurality of memristor devices from the influence factor; obtaining an input set of the algorithm model, and determining a criticality value for each of the plurality of memristor devices according to the way; determining a critical weight device among the plurality of memristor devices according to the criticality value for each of the plurality of memristor devices; and based on the critical weight device, performing an optimization processing on the first processing unit.

### CROSS-REFERENCE TO RELATED APPLICATION

The present application claims the priority to Chinese Patent Application No. 202110823231.2, filed on Jul. 21, 2021, the entire disclosure of which is incorporated herein by reference as a part of the present application.

### TECHNICAL FIELD

Embodiments of the present disclosure relates to a computing apparatus and a robustness processing method thereof.

### BACKGROUND

The in-memory computing technology base on a memristor is expected to break through the bottleneck of the von Neumann architecture of the classical computing system, bring about an explosive growth in hardware computing power and energy efficiency, and further promote the development and implementation of artificial intelligence, it is one of the most potential next-generation hardware chip technologies. Domestic and foreign enterprises and scientific research institutions have invested a lot of manpower and material resources. After nearly ten years of development, the in-memory computing technology base on the memristor has gradually entered a prototype demonstration stage of actual chips and systems from the theoretical simulation stage.

### SUMMARY

At least one embodiment of the present disclosure provides a robustness processing method of a computing apparatus, the computing apparatus including at least one processing unit, the at least one processing unit including a first processing unit, the first processing unit including a first computing memristor array, the first computing memristor array including a plurality of memristor devices arranged in an array, the method includes: based on model parameters of a target algorithm model, obtaining a mapping relationship between the model parameters and the first computing memristor array; based on an influence factor that determines a critical weight device, determining a way to obtain a weight criticality of the plurality of memristor devices from the influence factor; obtaining an input set of the algorithm model, and determining a criticality value for each of the plurality of memristor devices according to the way; determining a critical weight device among the plurality of memristor devices according to the criticality value for each of the plurality of memristor devices; and based on the critical weight device, performing an optimization processing on the first processing unit.

For example, in the robustness processing method of a computing apparatus provided by at least one embodiment of the present disclosure, a critical weight includes a first critical weight that is independent of a hardware of the first processing unit, and the influence factor that determines the critical weight device includes at least one first sub-influence factor, based on the influence factor that determines the critical weight device, determining a way to obtain a first weight criticality of the plurality of memristor devices from the influence factor, including: based on the at least one first sub-influence factor, determining a way to obtain a first weight criticality for each of the plurality of memristor devices from the first sub-influence factor.

For example, in the robustness processing method of a computing apparatus provided by at least one embodiment of the present disclosure, the at least one first sub-influence factor includes an importance factor for each of the plurality of memristor devices and/or a risk factor that affects a reliability of the first processing unit.

For example, in the robustness processing method of a computing apparatus provided by at least one embodiment of the present disclosure, the importance factor for each of the plurality of memristor devices includes a conductance value or a received input value for each of the plurality of memristor devices; the risk factor that affects the reliability of the first processing unit includes a hardware feature or an algorithm task feature of the first processing unit.

For example, in the robustness processing method of a computing apparatus provided by at least one embodiment of the present disclosure, based on the at least one first sub-influence factor, determining a way to obtain a first weight criticality for each of the plurality of memristor devices from the first sub-influence factor, including:
through formula (1):

$$f {1}_{i} = {\sum }_{i} [ {r}_{p} \cdot ( α \cdot g \cdot {x}_{i} + β \cdot r ( g ) ) ] \qquad ( 1 )$$

calculating a first weight criticality value of any memristor device R in the first computing memristor array for the input value xi, where f1ᵢ is the first weight criticality value of the memristor device R for the input value xᵢ, g is a conductance value of the memristor device R, p refers to the first processing unit or the first computing memristor array, xᵢ is an input value for the memristor device R in the i-th operation, r(g) is a reliability risk coefficient in the case where the conductance value is g, rₚ is a model risk of the first processing unit or the first computing memristor array, α is a hyperparameter corresponding to the importance factor, β is a hyperparameter corresponding to the risk factor.

For example, in the robustness processing method of a computing apparatus provided by at least one embodiment of the present disclosure, based on the at least one first sub-influence factor, determining a way to obtain a first weight criticality for each of the plurality of memristor devices from the first sub-influence factor, further including: for the memristor device R, accumulating the first weight criticality values of all the input values in a first input set to obtain a final first weight criticality value of the memristor device R.

For example, in the robustness processing method of a computing apparatus provided by at least one embodiment of the present disclosure, based on the at least one first sub-influence factor, determining a way to obtain a first weight criticality for each of the plurality of memristor devices from the first sub-influence factor, further including: obtaining the first input set by uniformly sampling a training set for the algorithm model.

For example, in the robustness processing method of a computing apparatus provided by at least one embodiment of the present disclosure, a critical weight includes a second critical weight related to the first processing unit, and the influence factor that determines the critical weight device includes at least one second sub-influence factor, based on the influence factor that determines the critical weight device, determining a way to obtain a second weight criticality of the plurality of memristor devices from the influence factor, including: based on the at least one second sub-influence factor, determining a way to obtain a second weight criticality for each of the plurality of memristor devices from the second sub-influence factor.

For example, in the robustness processing method of a computing apparatus provided by at least one embodiment of the present disclosure, the at least one second sub-influence factor includes: an on-chip calculation deviation, an algorithm model risk coefficient, or input values for the plurality of memristor devices.

For example, in the robustness processing method of a computing apparatus provided by at least one embodiment of the present disclosure, the on-chip calculation deviation includes: a first deviation between a first actual output value of each column of the first computing memristor array and a corresponding first ideal value, and/or a second deviation between a second actual output value of each neuron in a neural unit layer of the neural network where the first computing memristor array is located and a corresponding second ideal value.

For example, in the robustness processing method of a computing apparatus provided by at least one embodiment of the present disclosure, based on the at least one second sub-influence factor, determining a way to obtain a second weight criticality for each of the plurality of memristor devices from the second sub-influence factor, including:
through formula (2):

$$f {2}_{i} = {\sum }_{i} {r}_{p} \cdot ( α \cdot {x}_{i} \cdot {δ}_{i} ) \qquad ( 2 )$$

calculating a second weight criticality value of any memristor device R in the first computing memristor array for the input value xi, where f2ᵢ is the second weight criticality value of the memristor device R for the input value xᵢ, xᵢ is an input value for the memristor device R in the i-th operation, δᵢ is a first deviation or a second deviation of a column or a neuron where the memristor device R is located in the i-th operation, rₚ is a model risk coefficient of the first processing unit or the first computing memristor array, α is an importance coefficient and is a hyperparameter.

For example, in the robustness processing method of a computing apparatus provided by at least one embodiment of the present disclosure, based on the at least one second sub-influence factor, determining a way to obtain a second weight criticality for each of the plurality of memristor devices from the second sub-influence factor, further including: for the memristor device R, accumulating the second weight criticality values of all the input values in a second input set to obtain a final second weight criticality value of the memristor device R.

For example, in the robustness processing method of a computing apparatus provided by at least one embodiment of the present disclosure, based on the at least one second sub-influence factor, determining a way to obtain a second weight criticality for each of the plurality of memristor devices from the second sub-influence factor, further including: obtaining the second input set by uniformly sampling a training set for the algorithm model.

For example, in the robustness processing method of a computing apparatus provided by at least one embodiment of the present disclosure, based on the at least one second sub-influence factor, determining a way to obtain a second weight criticality for each of the plurality of memristor devices from the second sub-influence factor, further including: during a computing process, setting different weight coefficients for different input values.

For example, in the robustness processing method of a computing apparatus provided by at least one embodiment of the present disclosure, based on the critical weight device, optimizing the first processing unit, including: optimizing the critical weight devices by using an averaging strategy; and/or optimizing the critical weight devices by using a re-refreshing strategy.

For example, in the robustness processing method of a computing apparatus provided by at least one embodiment of the present disclosure, determining a critical weight device among the plurality of memristor devices based on the criticality value for each of the plurality of memristor devices, includes: among the plurality of memristor devices, selecting a memristor device with a criticality value greater than a threshold corresponding to the first processing unit as the critical weight device; or, among the plurality of memristor devices, selecting a device whose criticality value is within a first percentage of criticality values being sorted by size of the plurality of memristor devices as the critical weight device; or in each column of the plurality of memristor devices, selecting a device whose criticality value is within a second percentage of criticality values being sorted by size of the memristor device in the each column as the critical weight device.

For example, the robustness processing method of a computing apparatus provided by at least one embodiment of the present disclosure further includes: determining the algorithm model according to an application scenario, and training the algorithm model to obtain the model parameters.

For example, in the robustness processing method of a computing apparatus provided by at least one embodiment of the present disclosure, obtaining a mapping relationship between the model parameters and the first computing memristor array, includes: obtaining the model parameters through compiler deployment and division, and mapping a portion of the model parameters corresponding to the first computing memristor array to a plurality of memristor devices of the first computing memristor array.

At least one embodiment of the present disclosure provides a computing apparatus, including: a first computing module, a second computing module, a third computing module and an in-memory computing module, the in-memory computing module includes at least one processing unit and an optimization unit, the at least one processing unit includes a first processing unit, the first processing unit includes a first computing memristor array, and the first computing memristor array includes a plurality of memristor devices arranged in an array; the first computing module is configured to, based on model parameters of a target algorithm model, obtain a mapping relationship between the model parameters and the first computing memristor array, and based on an influence factor that determines a critical weight device, determine a way to obtain a weight criticality of the plurality of memristor devices from the influence factor; the second computing module is configured to, obtain an input set of the algorithm model, and determine a criticality value for each of the plurality of memristor devices according to the way; the third computing module is configured to determine a critical weight device among the plurality of memristor devices according to the criticality value for each of the plurality of memristor devices; the optimization unit is configured to perform optimization processing on the first processing unit based on the critical weight device.

At least one embodiment of the present disclosure provides a computing apparatus, including: a first computing sub-apparatus and an in-memory computing module, where the in-memory computing module includes at least one processing unit and an optimization unit, the at least one processing unit includes a first processing unit, the first processing unit includes a first computing memristor array, and the first computing memristor array includes a plurality of memristor devices arranged in an array; the first computing sub-apparatus includes: a processor and a memory, where the memory stores a computer executable program, and the computer executable program, when executed by the processor, is configured to implement the following method; based on model parameters of a target algorithm model, obtaining a mapping relationship between the model parameters and the first computing memristor array; based on an influence factor that determines a critical weight device, determining a way to obtain a weight criticality of the plurality of memristor devices from the influence factor; obtaining an input set of the algorithm model, and determine a criticality value for each of the plurality of memristor devices according to the way; determining a critical weight device among the plurality of memristor devices according to the criticality value for each of the plurality of memristor devices; and based on the critical weight device, providing an instruction for performing optimization processing on the first processing unit, the optimization unit is configured to, based on the critical weight device, perform an optimization processing on the first processing unit according to the instruction.

For example, in the computing apparatus provided by at least one embodiment of the present disclosure, the optimization unit includes a redundant weight processing unit, which includes a first redundant memristor array, columns of the first redundant memristor array are in one-to-one correspondence with columns of the first computing memristor array to share the same bit line, rows of the first redundant memristor array are parallel to rows of the first computing memristor array.

For example, in the computing apparatus provided by at least one embodiment of the present disclosure, the optimization unit includes a refreshing control unit, which is configured to re-refreshing the critical weight device.

For example, in the computing apparatus provided by at least one embodiment of the present disclosure, the in-memory computing module further includes a critical weight control unit, which is configured to select and process the critical weight device.

For example, in the computing apparatus provided by at least one embodiment of the present disclosure, the in-memory computing module further includes a deviation computing and processing unit, and the deviation computing and processing unit is configured to: receive a first actual output value of each column of the first computing memristor array during an operation process and receive a corresponding first ideal value, and obtain a first deviation between the first actual output value and the first ideal value, and/or receive a second actual output value of each neuron in a neural unit layer of the neural network where the first computing memristor array is located and a corresponding second ideal value, and obtain a second deviation between the second actual output value and the second ideal value.

### BRIEF DESCRIPTION OF DRAWINGS

In order to more clearly explain the technical scheme of the embodiments of the present disclosure, the attached drawings of the embodiments will be briefly introduced below. Obviously, the attached drawings in the following description only relate to some embodiments of the present disclosure, and are not limited to the present disclosure.

FIG. 1 illustrates a schematic diagram of a processing unit of a computing apparatus;

FIG. 2 illustrates a schematic diagram of a memristor cross array structure;

FIG. 3 illustrates a schematic diagram of memristor device deviation caused by volatility;

FIG. 4 illustrates a schematic diagram of model risk coefficient assignment of a computing apparatus;

FIG. 5A illustrates a flowchart of a robustness processing method of a computing apparatus provided by at least one embodiment of the present disclosure;

FIG. 5B illustrates a flowchart of a robustness processing method based on a weight criticality determination method that is relevant to hardware provided by at least one embodiment of the present disclosure;

FIG. 6A illustrates a schematic diagram of calculating deviations based on column output of a processing unit provided by at least one embodiment of the present disclosure;

FIG. 6B illustrates a schematic diagram of calculating deviations based on outputs of neurons of a layer provided by at least one embodiment of the present disclosure;

FIG. 7A illustrates a schematic diagram of calculating criticality of each device in the processing unit under one input provided by at least one embodiment of the present disclosure;

FIG. 7B illustrates a schematic diagram of a process for calculating device unit criticality based on column deviations of a processing unit provided by at least one embodiment of the present disclosure;

FIG. 7C illustrates a schematic diagram of a process for calculating device unit criticality based on neuron deviations of a layer provided by at least one embodiment of the present disclosure;

FIG. 8A illustrates a schematic diagram of improving computing robustness by an averaging method for a critical weight provided by at least one embodiment of the present disclosure;

FIG. 8B illustrates a schematic diagram of improving computing robustness by re-mapping refreshing of a critical weight provided by at least one embodiment of the present disclosure;

FIG. 9 illustrates a processing unit structure for determining and improving system robustness with respect to a critical weight provided by at least one embodiment of the present disclosure;

FIG. 10A illustrates a schematic diagram of a computing apparatus provided by at least one embodiment of the present disclosure;

FIG. 10B illustrates a schematic diagram of another computing apparatus provided by at least one embodiment of the present disclosure; and

FIG. 10C illustrates a schematic diagram of another computing apparatus provided by at least one embodiment of the present disclosure.

### DETAILED DESCRIPTION

In order to make the purpose, technical scheme and advantages of the embodiment of the disclosure more clear, the technical scheme of the embodiment of the disclosure will be described clearly and completely with the attached drawings. Obviously, the described embodiment is a part of the embodiment of the present disclosure, not the whole embodiment. Based on the described embodiments of the present disclosure, all other embodiments obtained by ordinary people in the field without creative labor belong to the scope of protection of the present disclosure.

Unless otherwise defined, technical terms or scientific terms used in this disclosure shall have their ordinary meanings as understood by people with ordinary skills in the field to which this disclosure belongs. The terms “first”, “second” and the like used in this disclosure do not indicate any order, quantity or importance, but are only used to distinguish different components. Similarly, similar words such as “a”, “an” or “the” do not indicate a quantity limit, but indicate the existence of at least one. Similar words such as “including” or “containing” mean that the elements or objects appearing before the word cover the elements or objects listed after the word and their equivalents, without excluding other elements or objects. Similar words such as “connected” or “connected” are not limited to physical or mechanical connection, but can include electrical connection, whether direct or indirect. “Up”, “Down”, “Left” and “Right” are only used to indicate the relative positional relationship. When the absolute position of the described object changes, the relative positional relationship may also change accordingly.

Hereinafter, the present disclosure will be explained by several specific embodiments. In order to keep the following description of the embodiments of the present disclosure clear and concise, detailed descriptions of known functions and known components may be omitted. When any component of an embodiment of the present disclosure appears in more than one drawing, the component is represented by the same reference numeral in each drawing.

An in-memory computing technology can be realized based on a memristor, and a matrix-vector multiplication calculation can be completed in high parallel without accessing memory and moving weight data. Computing functions based on a memristor array can be implemented through an integrated circuit technology, forming a basic computing acceleration module, which is called a processing unit. A computing apparatus provided by an embodiment of the present disclosure includes a plurality of processing units.

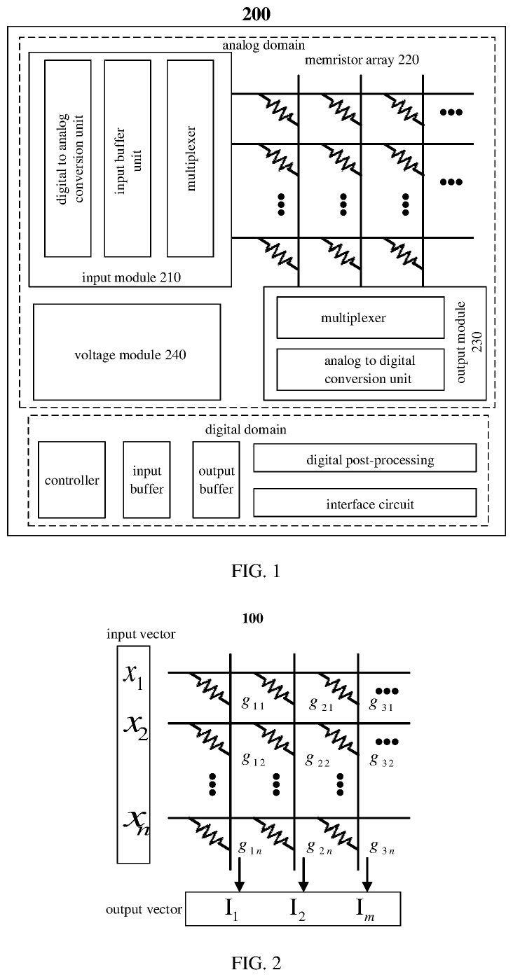

FIG. 1 illustrates a schematic diagram of a processing unit of a computing apparatus, which can be configured to realize an in-memory computing apparatus. As illustrated in FIG. 1, the processing unit 200 may include an analog domain portion and a digital domain portion, the analog domain portion implements analog computing based on analog signals, an input, a control, and an output of the analog domain are all digital signals; the digital domain portion controls and cooperates with the functions of the analog domain portion and interacts with the outside.

For example, as illustrated in FIG. 1, the analog domain portion may include an input module 210, a memristor array 220, an output module 230, and a voltage module 240. The input module 210 is a related analog circuit configured to implement an input vector function; the memristor array 220 is a memristor cross array (such as the memristor cross array structure 100 illustrated in FIG. 2, further referred to as “memristor array” below), which can be written into a weight matrix and perform a multiplication-accumulation calculation; the output module 230 is a related analog circuit configured to realize a quantization of an output vector (such as output current illustrated in FIG. 2); the voltage module 240 is a basic analog power circuit. For example, the digital domain portion may include a controller, input buffer, output buffer, a digital post-processing module, an interface module, etc.

It should be noted that the processing unit 200 illustrated in FIG. 1 is only exemplary and does not limit the present disclosure, the processing unit can add, delete, and deform modules according to actual conditions.

FIG. 2 illustrates a schematic diagram of a memristor cross array structure. As illustrated in FIG. 2, the memristor cross array structure 100 may include a plurality of memristors arranged in a horizontal and vertical cross array, by arranging input data into an input vector X (for example, including x₁, x₂, . . . , xₙ as illustrated in FIG. 2, and the input vector can be a voltage with an encoded amplitude, width or number of pulses), encoding the weight matrix as a memristor conductance value G (for example, including, g₁₁, g₂₁, . . . , g₁ₙ illustrated in FIG. 2, and gₘ₁, gₘ₁, . . . , gₘₙ not illustrated in FIG. 2), and using a highly parallel, low-power array reading operation to obtain output current I (for example, including I₁, I₂, . . . , Iₘ illustrated in FIG. 2), a multiplication-accumulation calculation that is common in deep learning can be achieved, thereby accelerating matrix-vector multiplication.

For example, according to Kirchhoffs law, the output current of the memristor cross array structure can be obtained according to the following formula: I=G×X. For example, I₁=x₁g₁₁+x₂g₁₂+ . . . +xₙg₁ₙ. The above multiplication-accumulation calculation process is implemented using the laws of physics, and is different from a digital circuit implementation of Boolean logic, it does not require frequent accessing memory and moving weight data, the von Neumann bottleneck of the classic computing system can be solved and can achieve an intelligent computing task with a high computing power and a high energy efficiency.

As described above, each processing unit includes a memristor array, which includes a plurality of memristor devices arranged in an array. The memristor device can be, for example, a resistive random access memory, a phase change memory, a ferroresistive change device, a magnetic tunneling device or a traditional FLASH flash memory device. The memristor device can be of 1T1R (one switching transistor, one memristor), 2T2R (two switching transistors, two memristors) and other types. The present disclosure does not limit the type and structure of the memristor device.

In the above memristor arrays configured for calculations, the memristor devices face reliability problems and has inevitable fluctuations, noise, and state drift, which cause calculation errors and affect a normal function of the system. In the case where the conductance value of a memristor device is configured for a simulation calculation, because of volatility and other non-ideal characteristics of the memristor device, for example, a random fluctuation, a relaxation characteristic, a retention characteristic, etc. of the memristor device, an actual conductance value will deviate from an ideal conductance value, which causes deviations in calculation results.

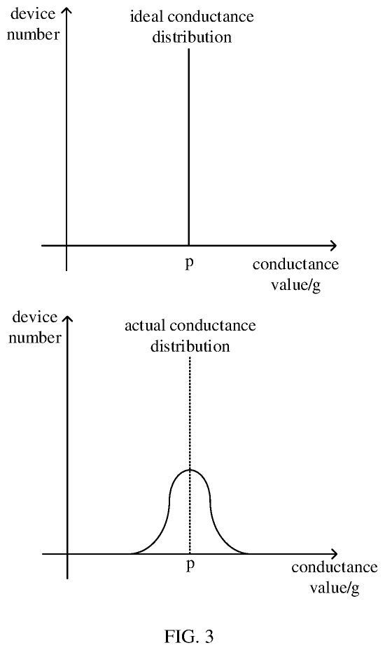

FIG. 3 illustrates a schematic diagram of memristor device deviation caused by volatility. As illustrated in an upper half of FIG. 3, in the case of ideal conductance distribution, the conductance value distribution is a straight line; and as illustrated in a lower half of FIG. 3, in the case of actual conductance value distribution, the conductance value will appear deviations and distributed within a conductivity interval.

In order to solve the problems caused by memristor device errors and improve the robustness of computing apparatus, some optimization methods have been proposed, mainly focusing on three aspects: (1) directly improving characteristics of the memristor device through mechanism research and optimization on structure and material; (2) for each weight unit in the system, adopting a strategy of joint representation of a plurality of memristor devices, and offsetting an impact of the reliability of the memristor devices on the overall weight unit through an average idea; (3) regularly refreshing all weight units in the system, reading and verifying all weight values, and reprograming the device weights that do not meet requirements. In addition, there are some system-level algorithm optimizations, such as updating the memristor array of some or all critical layers on-chip to be compatible with the memristor device errors.

However, in practice, in the case where each memristor array participates in a calculation, not all memristor devices in the memristor array will experience an error fluctuation event, the weight of each memristor device has different importance to the calculation results and a size of the error caused. By optimizing the structure and material of the memristor device to improve the reliability of the memristor device and improve the system robustness, a cost is high and a cycle is long, there are currently no good technical solutions and breakthroughs; by a method of regularly refreshing the weights of all the memristor devices or adopting the average strategy of using a plurality of memristor devices to represent a weight has high overhead, a high cost, and will reduce chip area utilization. A system-level algorithm adjustment is aimed at the memristor array corresponding to the critical layer or all memristor devices in the all memristor arrays, which also has a high cost.

At least one embodiment of the present disclosure provides a computing apparatus and a robustness processing method thereof. The computing apparatus includes at least one processing unit, the at least one processing unit includes a first processing unit including a first computing memristor array, and the first computing memristor array includes a plurality of memristor devices arranged in an array. The robustness processing method includes: based on model parameters of a target algorithm model, obtaining a mapping relationship between the model parameters and the first computing memristor array; based on an influencing factor that determines the critical weight device, determining a way to obtain a weight criticality of the plurality of memristor devices from the influence factor; obtaining an input set of the algorithm model, and according to the above way, determining a criticality value for each of the plurality of memristor devices; determining a critical weight device among the plurality of memristor devices according to the criticality value for each of the plurality of memristor devices; and based on the critical weight device, performing an optimization processing on the first processing unit.

The robustness processing method of the computing apparatus provided by at least one embodiment of the present disclosure can realize low-cost, highly robustness computing apparatus by specifically performing a target robustness improvement on some critical memristor devices.

For example, at least one embodiment of the present disclosure ranks the importance and reliability of each memristor device, determines the critical weight, and performs a reliability improvement design for the memristor device with the critical weight, without having to perform a reliability improvement design on all memristor devices, which reduces the cost.

Hereinafter, the robustness processing method of the computing apparatus proposed by the present disclosure, its embodiments and corresponding examples will be described in detail with reference to the accompanying drawings.

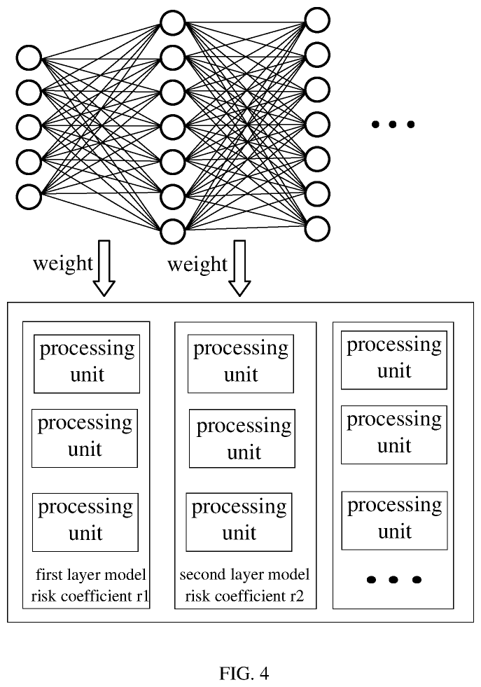

FIG. 4 illustrates a schematic diagram of model risk coefficient assignment of a computing apparatus. As illustrated in FIG. 4, for any algorithm model (for example, an image recognition model, a sound recognition model, etc., these algorithm models are based on, for example, neural networks, such as convolutional neural networks), the model parameters of the algorithm model are obtained by training the algorithm model. The computing apparatus includes at least one processing unit, the processing unit includes a memristor array. The compiler deploys and divides the model parameters into each processing unit, based on a mapping relationship between the model parameters and the memristor array, a portion of the model parameters corresponding to the memristor array is mapped to a plurality of memristor devices of the memristor array. Because parameter changes at different layers, positions and types in the algorithm model have different effects on the algorithm, different model risk coefficients can be assigned to corresponding processing units, the model risk coefficient reflects a sensitivity of a system function to the parameter changes in different neural network layers, the processing units in the same layer usually have the same value.

For example, as illustrated in FIG. 4, the processing units corresponding to the first layer of the algorithm model is assigned a first layer model risk coefficient r1, and the processing units corresponding to the second layer of the algorithm model is assigned a second layer model risk coefficient r2, and settings are similar in sequence.

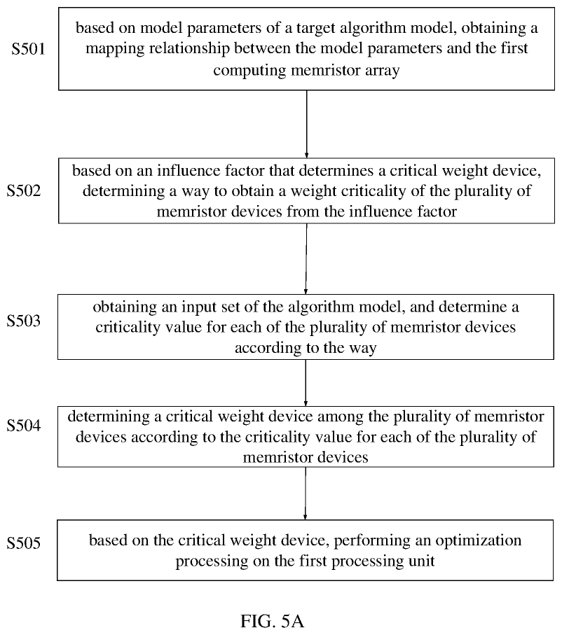

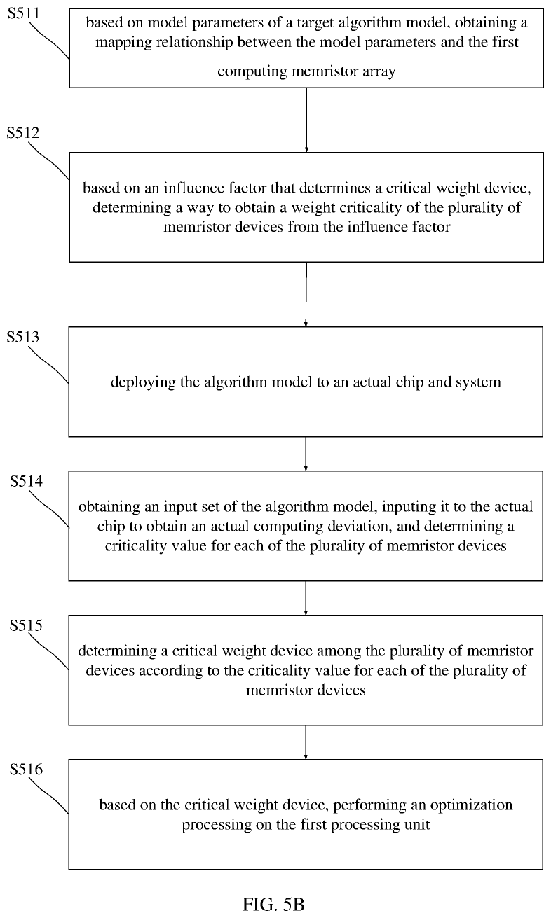

FIG. 5A illustrates a flowchart of a robustness processing method of a computing apparatus provided by at least one embodiment of the present disclosure.

As illustrated in FIG. 5A, the robustness processing method of the computing apparatus is, for example, configured for a computing apparatus including an in-memory computing module as illustrated in FIG. 1 or FIG. 4. For example, the computing apparatus includes at least one (for example, a plurality of) processing unit, the at least one processing unit including a first processing unit, the first processing unit includes a first computing memristor array, which includes a plurality of memristor devices arranged in an array. The robustness processing method of the computing apparatus includes steps S501 to S505,

Step S501: based on model parameters of a target algorithm model, obtaining a mapping relationship between the model parameters and the first computing memristor array.

Step S502: based on an influence factor that determines a critical weight device, determining a way to obtain a weight criticality of the plurality of memristor devices from the influence factor.

Step S503: obtaining an input set of the algorithm model, and determining a criticality value for each of the plurality of memristor devices according to the way.

Step S504: determining a critical weight device among the plurality of memristor devices according to the criticality value for each of the plurality of memristor devices.

Step S505: based on the critical weight device, performing an optimization processing on the first processing unit.

The robustness processing method of the above embodiment can realize a low-cost, highly robustness computing apparatus by only performing a target robustness improvement on some critical memristor devices in the computing apparatus.

The following is a further exemplary description of the above steps S501 to S505.

For step S501, the target algorithm model can be determined according to an application scenario, and the model parameters can be obtained by training the algorithm model. As mentioned above, according to different application scenarios, the algorithm model can be, for example, an image recognition model, a sound recognition model, etc., these algorithm models are, for example, based on neural networks (such as convolutional neural networks), which is not limited by the embodiments of the present.

For example, at step S501, the model parameters are deployed and divided into each processing unit by tools such as a compiler, and the portion of the model parameters corresponding to the computing memristor array in each processing unit is mapped to the plurality of memristor devices of the computing memristor array, to obtain the mapping relationship between the model parameters and the computing memristor array, for example, the mapping relationship illustrated in FIG. 4. For example, a portion of the model parameters corresponding to the first computing memristor array may be mapped to a plurality of memristor devices of the first computing memristor array.

For step S502, for example, based on the influence factor determining the critical weight device, the method of determining the weight criticality of the plurality of memristor devices based on the influence factor may be a weight criticality determination method that is independent of hardware, or it may be a weight criticality determination method that is relevant to hardware.

On the one hand, the weight criticality determination method that is independent of hardware is decoupled from an actual chip and can be fully integrated in tools such as a compiler, which can be determined before specific deployment without adding additional hardware cost.

On the other hand, the weight criticality determination method that is relevant to hardware is to transmit the input to a physical chip, obtain an actual output of each processing unit (on-chip test result), and determine the weight criticality based on the on-chip test results.

A weight criticality determination that is independent of hardware and a weight criticality determination that is relevant to hardware can be performed independently of each other to improve the robustness of the computing apparatus, or they can be combined to better improve the robustness of the computing apparatus.

The weight criticality determination that is independent of hardware and the weight criticality determination that is relevant to hardware will further be described below respectively.

For step S503, for example, the training set configured for the algorithm model is uniformly sampled to obtain a first input set, and the criticality value for each of the plurality of memristor devices is calculated according to the weight criticality determination method that is independent of hardware; or, the training set configured for the algorithm model is uniformly sampled to obtain a second input set, and the criticality value for each of the plurality of memristor devices is calculated according to the weight criticality determination method that is relevant to hardware.

For step S504, for example, specific rules can be designed to determine the critical weight based on the criticality value for each of the plurality of memristor devices. The rule is, for example, a fixed threshold method or a fixed ratio method, but the embodiments of the present disclosure do not limit this.

For example, the fixed threshold method includes: setting a fixed threshold in advance, and selecting a memristor device with a criticality value greater than the threshold corresponding to the first processing unit as a critical weight device among the plurality of memristor devices.

For another example, the fixed ratio method includes: presetting one or more fixed ratios (such as a first fixed ratio and a second fixed ratio below), and among the plurality of memristor devices, selecting devices whose criticality value is within a first fixed ratio (for example, the top 20%) of the criticality values being sorted by size of the plurality of memristor devices as the critical weight devices; or, among each column of plurality of memristor devices, selecting devices whose criticality values are within a second fixed ratio (for example, the top 10%) of the criticality values being sorted by size of the devices of the each column as critical weight devices.

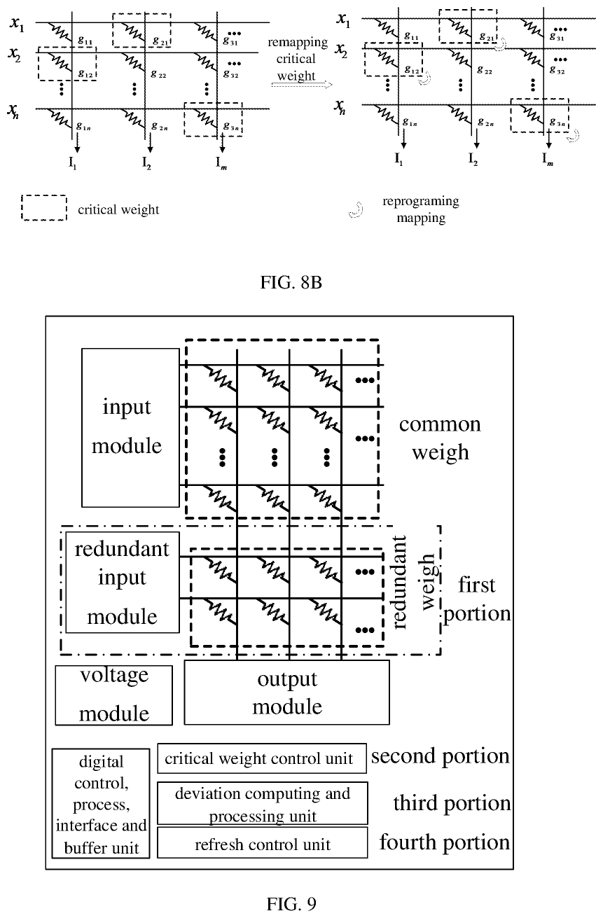

For step S505, after the critical weight is determined, the reliability optimization method can be combined to improve the robustness of the computing apparatus. For example, a redundant backup setting can be set for the critical weight device, so that the average strategy can be configured for optimization on the critical weight device; a re-refreshing strategy can be configured for optimization on the critical weight device. The reliability optimization method will be described later with reference to FIG. 8A and FIG. 8B.

In at least one embodiment of the present disclosure, the robustness processing method provided is based on a weight criticality determination method that is independent of hardware. The robustness processing method based on the weight criticality determination method that is independent of hardware can refer again to the flowchart illustrated in FIG. 5A, which, for example, locates the critical weight device in the memristor array by calculating the influence factor of each weight device in each processing unit.

In the embodiment of the weight criticality determination method that is independent of hardware, at step S502, specifically, the critical weight is a first critical weight that is independent of the hardware of the processing unit, and the influence factor that determines the critical weight device includes at least one first sub-critical weight, the at least one first sub-influence factor, for example, includes an importance factor for each of the plurality of memristor devices and/or a risk factor that affects the reliability of the processing unit.

For example, the importance factor can be a conductance value of the memristor device, an input value received by each weight, etc. The risk factors that affect reliability can be a feature of the hardware itself, an algorithm task feature, etc. For the feature of the hardware itself, one situation is that the reliability of the memristor device is related to a state conductance of the memristor device, so memristor devices with different state conductance have different risk coefficients; for the algorithm task feature, another situation is that because parameter changes in different layers, positions and types in the neural network model have different effects on the algorithm, different coefficients can be assigned to the corresponding processing units, for example the risk coefficient assignment illustrated in FIG. 4. The embodiments of the present disclosure do not limit this, and the influence factors can be flexibly selected and constructed according to different algorithm task types.

After determining the first sub-influence factor that determines the critical weight, determine a calculation function to obtain the first weight criticality from the first sub-influence factor, so as to determine a critical weight position (that is, the critical weight device) in the processing unit that contributes greatly to the output and is prone to errors through the first sub-influence factor.

For example, based on the at least one first sub-influence factor, the first weight criticality value for the input value of any memristor device R in the first computing memristor array is calculated through the following formula (1):

$$f {1}_{i} = {\sum }_{i} [ {r}_{p} \cdot ( α \cdot g \cdot {x}_{i} + β \cdot r ( g ) ) ] \qquad ( 1 )$$

where f1ᵢ is the first weight criticality value of the memristor device R for the input value xᵢ,
g is a conductance value of the memristor device R,
p refers to the first processing unit or the first computing memristor array,
xᵢ is an input value for the memristor device R in the i-th operation,
r(g) is a reliability risk coefficient in the case where the conductance value is g,
rₚ is a model risk of the first processing unit or the first computing memristor array,
α is a hyperparameter corresponding to the importance factor,
β is a hyperparameter corresponding to the risk factor.

For the input value xi, etc., for example, all inputs can be normalized in advance. The model risk rₚ reflects a sensitivity of the system function to deviations of different layers. For example, as illustrated in FIG. 4, the processing units in the same layer usually have the same value, the memristor arrays corresponding to the same processing unit have the same value. In addition, it should be noted that the hyperparameter can be pre-selected, and the specific value can be determined through searching, which may involve a plurality of attempts or exhaustion; once determined, the value of the hyperparameter is usually fixed in the algorithm model.

For example, formula (1) can be configured to perform an accumulation operation of the first weight criticality values of all input values in the first input set, and a result of the accumulation operation is the final first weight criticality value of the memristor device R. In at least one example, the first input set may be obtained by uniformly sampling the training set configured for the algorithm model, and the embodiments of the present disclosure do not limit this.

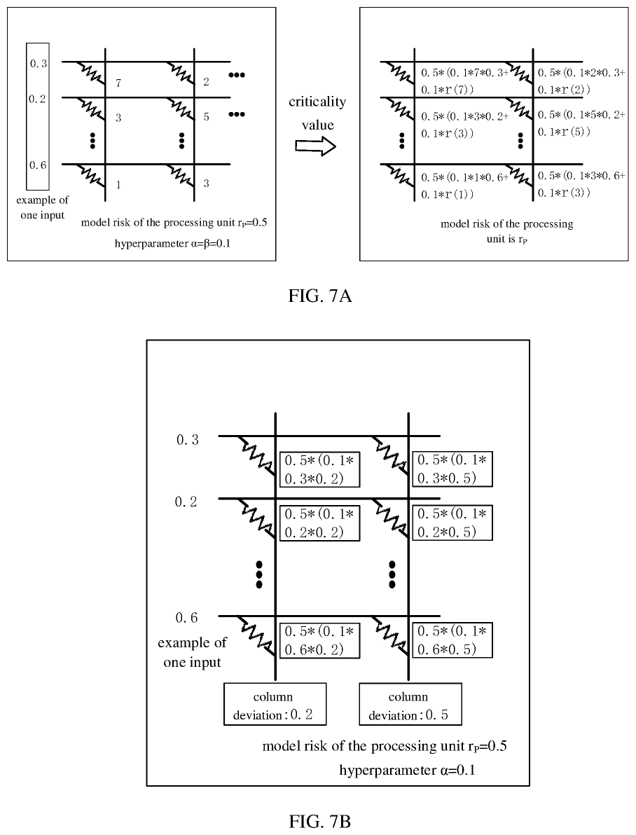

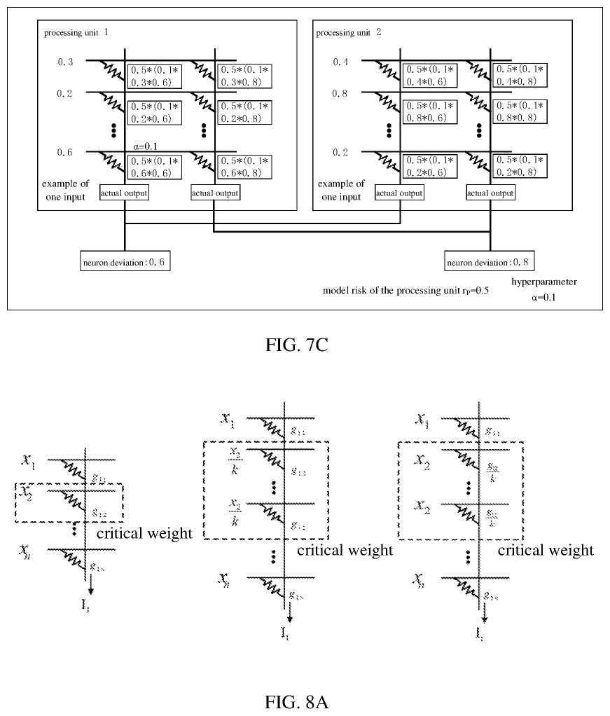

FIG. 7A illustrates a calculation schematic diagram of criticality of each device in the processing unit under one input in the above embodiment of the present disclosure.

As illustrated in FIG. 7A, for example, in this example, the model risk coefficient of the processing unit rₚ=0.5, and the hyperparameter α=β=0.1. An input of the first row of the memristor array in this processing unit is 0.3, an input of the second row is 0.2, . . . , and an input of the nth row is 0.6. The conductance of each memristor illustrated in the memristor array is respectively set to g₁₁=7, g₂₁=2, g₁₂=3, g₂₂=5, . . . , g₁ₙ=1, g₂ₙ=3. According to the above formula (1), it can be obtained that under this input, the first weight criticality value of each memristor device in the memristor array for the input value is as follows:

$$Memristor device {R}_{11} = 0.5 * ( 0.1 * 7 * 0.3 + 0.1 * r ( 7 ) ) , \\ Memristor device {R}_{21} = 0.5 * ( 0.1 * 2 * 0.3 + 0.1 * r ( 2 ) ) , \\ Memristor device {R}_{22} = 0.5 * ( 0.1 * 5 * 0.2 + 0.1 * r ( 5 ) ) , \\ … \\ Memristor device {R}_{1 n} = 0.5 * ( 0.1 * 1 * 0.6 + 0.1 * r ( 1 ) ) , \\ Memristor device {R}_{2 n} = 0.5 * ( 0.1 * 3 * 0.6 + 0.1 * r ( 3 ) ) , etc .$$

In the above example, the weight criticality determination method that is independent of hardware can be decoupled from an actual chip and a system, and can be integrated into an algorithm compilation process, which is more convenient and faster, for example, which can be determined before specific deployment without adding additional hardware cost.

In addition, because of randomness of noise such as memristor device fluctuations, a deviation often exist between a positioned critical weight and an actual object. In order to achieve a more reliable weight criticality determination method, another embodiment of the present disclosure involves a robustness processing method based on a weight criticality determination method that is relevant to hardware, which can eliminate the randomness of noise such as the memristor device fluctuations and achieve more reliable weight criticality determination.

FIG. 5B illustrates a flowchart of a robustness processing method based on a weight criticality determination method that is relevant to hardware provided by at least one embodiment of the present disclosure.

As illustrated in FIG. 5B, the robustness processing method of the computing apparatus in this embodiment includes steps S511 to S516.

Step S511 is the same as step S501 in FIG. 5A, step S515 is the same as step S504 in FIG. 5A, and step S516 is the same as step S505 in FIG. 5A, which will not be described again here.

In this embodiment, in step S512, the critical weight is a second critical weight that is relevant to the hardware of the processing unit, and the influence factor that determines the critical weight device includes at least one second sub-influence factor. The at least one second sub-influence factor includes, for example, an on-chip calculation deviation, an algorithm model risk coefficient, or input values for the plurality of memristor devices.

The on-chip calculation deviation can represent a deviation between an output value and an ideal value of each column of each processing unit, or the deviation between an actual output value and the ideal value of the neuron in each layer of the network (calculated at different layers of the neural network). In an in-memory computing system, the parameters of each layer of the neural network usually need to be deployed on a plurality of processing units, so the output deviation of the neuron is an overall deviation corresponding to a joint action of the plurality of processing units.

After determining the second sub-influence factor that determines the critical weight, determine a calculation function to obtain the second weight criticality from the second sub-influence factor, so as to determine a critical weight position in the processing unit that contributes greatly to the output and is prone to errors through the second sub-influence factor.

For example, based on the at least one second sub-influence factor, the second weight criticality value for the input value xi for any memristor device in the first computing memristor array is calculated through formula (2):

$$f {2}_{i} = {\sum }_{i} {r}_{p} \cdot ( α \cdot {x}_{i} \cdot {δ}_{i} ) \qquad ( 2 )$$

where, xᵢ is an input value for the memristor device R in the i-th operation,
δᵢ is a first deviation or a second deviation of a column or a neuron where the memristor device R is located in the i-th operation,
rₚ is a model risk coefficient of the first processing unit or the first computing memristor array,
α is an importance coefficient and is a hyperparameter.

It should be noted that the hyperparameter can be pre-selected, and the specific value can be determined through searching, which may involve a plurality of attempts or exhaustion; once determined, the value of the hyperparameter is usually fixed in the algorithm model. Because the critical weight is determined based on the on-chip calculation deviation, a risk factor related to a size and a state of a conductance weight itself is usually no longer introduced.

In addition, in at least one embodiment, during the calculation process, different weight coefficients can be set for different input values according to actual working conditions, to enhance an impact of specific inputs on positioning the critical weights. For example, a weight for an important input value can be increased and a weight for an unimportant input value can be decreased.

The above formula (2) is an accumulation operation of the second weight criticality values of all input values in the second input set, and the second input set can be obtained by uniformly sampling the training set configured for the algorithm model, and a result of the accumulation operation is the final second weight criticality value of the memristor device R.

In step S513, deploying the algorithm model to an actual chip (such as a chip where the in-memory computing module is located) or system, so that actual inputs and outputs can be collected.

In step S514, for example, obtaining the second input set of the algorithm model by uniformly sampling the training set for the algorithm model, and in a case where the weight criticality determination method that is relevant to hardware is adopted, inputting the second input set to the actual chip to obtain an actual computing deviation, so that the criticality value for each of the plurality of memristor devices is determined.

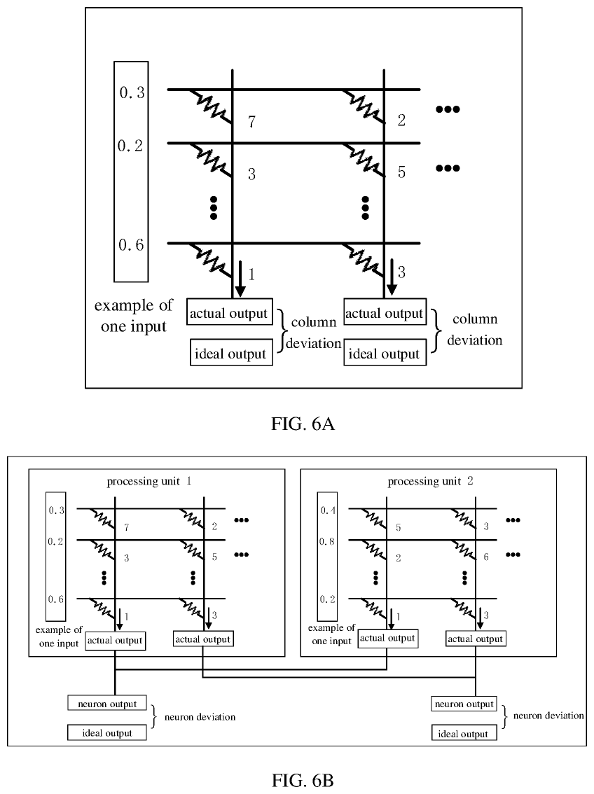

In this embodiment, for example, at least two ways can be configured to calculate the deviation, one is to calculate the deviation between the output value and the ideal value of each column of each processing unit, and the other is to calculate the deviation between the output value and the ideal value of the neuron of each layer of the neural network, the two ways of calculating the deviation are schematically illustrated in FIG. 6A and FIG. 6B respectively.

The weight criticality determination method that is relevant to hardware of this embodiment locates the critical weight through an operating deviation on the physical chip and the system, which can more comprehensively cover all noise and fluctuation factors, this process and the results are more accurate and reliable.

FIG. 6A illustrates a schematic diagram of a method for outputting calculating deviations based on column of a processing unit provided by at least one embodiment of the present disclosure.

As illustrated in FIG. 6A, the processing unit includes a memristor cross array structure, an input value set X (for example, x₁=0.3, x₂=0.2, . . . , xₙ=0.6) is given, a weight matrix is encoded as a memristor conductance value G (g₁₁=7, g₂₁=2, g₁₂=3, g₂₂=5, . . . , g₁ₙ=1, g₂ₙ=3), an actual output value of each column of the weight matrix is obtained by using a high-parallel and low-power array reading operation, and an ideal output value of each column of the weight matrix is obtained through a multiplication-accumulation operation I=G×X, the deviation between the ideal output value and the actual output value of each column of the weight matrix is a column deviation of the column.

FIG. 6B illustrates a schematic diagram of outputting calculating deviations based on neurons of a layer provided by at least one embodiment of the present disclosure.

In an in-memory computing system, parameters of one layer of a neural network usually need to be deployed on a plurality of processing units, so an output deviation of the neuron based on the layer is an overall deviation corresponding to a joint action of the plurality of processing units. In FIG. 6B, two processing units jointly constituting neurons in the same layer of the neural network is taking as an example for illustration.

As illustrated in FIG. 6B, for a first processing unit, an input value set is given (for example, x₁=0.3, x₂=0.2, . . . , xₙ=0.6), a weight matrix is encoded as a memristor conductance value G (g₁₁=7, g₂₁=2, g₁₂=3, g₂₂=5, . . . , g₁ₙ=1, g₂ₙ=3), an actual output value of each column of the weight matrix is obtained by using a high-parallel and low-power array reading operation, and an ideal output value of each column of the weight matrix is obtained through a multiplication-accumulation operation I=G×X. For a second processing unit, an input value set is given (for example, x₁=0.4, x₂=0.8, . . . , xₙ=0.2), a weight matrix is encoded as a memristor conductance value G (g₁₁=5, g₂₁=3, g₁₂=2, g₂₂=6, . . . , g₁ₙ=1, g₂ₙ=3), an actual output value of each column of the weight matrix is obtained by using a high-parallel and low-power array reading operation, and an ideal output value of each column of the weight matrix is obtained through a multiplication-accumulation operation I=G×X. A sum of an actual output value of the first column of the memristor array in the first processing unit and an actual output value of the first column of the memristor array in the second processing unit is a first neuron output. A sum of an ideal output value of the first column of the memristor array in the first processing unit and an ideal output value of the first column of the memristor array in the second processing unit is a first ideal output. A difference between the first neuron output and the first ideal output is a first neuron deviation. In the same way, a difference between a second neuron output and a second ideal output is a second neuron deviation.

In this embodiment, by introducing an influencing factor of on-chip calculation deviation (a result of the joint action of various unreliable factors), the randomness of noise such as memristor device fluctuations can be eliminated, which makes the positioning results of critical weights more reliable.

FIG. 7B illustrates a schematic diagram of a process for calculating device unit criticality based on column deviations of a processing unit under one input in the above embodiment of the present disclosure.

As illustrated in FIG. 7B, for example, the model risk coefficient of the processing unit rₚ=0.5 and the hyperparameter α=0.1. An input of the first row of the memristor array in this processing unit is 0.3, an input of the second row is 0.2, . . . , and an input of the nth row is 0.6. A column deviation of the first column of the memristor array is 0.2, and a column deviation of the second column is 0.5. According to formula (2), it can be obtained that under this input, the second weight criticality value of each memristor device in the memristor array for the input value is as follows:

$$Memristor device {R}_{11} = 0.5 * ( 0.1 * 0.3 * 0.2 ) , \\ Memristor device {R}_{21} = 0.5 * ( 0.1 * 0.3 * 0.5 ) , \\ Memristor device {R}_{12} = 0.5 * ( 0.1 * 0.2 * 0.2 ) , \\ Memristor device {R}_{22} = 0.5 * ( 0.1 * 0.2 * 0.5 ) , \\ … \\ Memristor device {R}_{1 n} = 0.5 * ( 0.1 * 0.6 * 0.2 ) , \\ Memristor device {R}_{2 n} = 0.5 * ( 0.1 * 0.6 * 0.5 ) .$$

FIG. 7C illustrates a schematic diagram of the process of calculating device unit criticality based on neuron deviations of the same layer in the neural network under one input in the above embodiment. Calculations of neural units in the same layer can be assigned to a plurality of processing units to complete together, and two processing units are taken as an example here.

As illustrated in FIG. 7C, for example, the model risk coefficient of the two processing units rₚ=0.5 and the hyperparameter α=0.1. An input of the first row of the memristor array in a first processing unit is 0.3, an input of the second row is 0.2, . . . , and an input of the nth row is 0.6. An input of the first row of the memristor array in the second processing unit is 0.4, an input of the second row is 0.8, . . . , and an input of the nth row is 0.2. A column deviation of the first column of the memristor array is 0.2, and a column deviation of the second column is 0.5. A first neuron deviation is an overall deviation of the first column of the first processing unit and the first column of the second processing unit acting together, which is 0.6. The second neuron deviation is an overall deviation of the second column of the first processing unit and the second column of the second processing unit acting together, which is 0.8. According to formula (2), it can be obtained that under this input, the second weight criticality value of each memristor device in the memristor array for the input value is as follows:

$$Memristor device {R}_{11} = 0.5 * ( 0.1 * 0.3 * 0.6 ) , \\ Memristor device {R}_{21} = 0.5 * ( 0.1 * 0.3 * 0.8 ) , \\ Memristor device {R}_{12} = 0.5 * ( 0.1 * 0.2 * 0.6 ) , \\ Memristor device {R}_{22} = 0.5 * ( 0.1 * 0.2 * 0.8 ) , \\ … \\ Memristor device {R}_{1 n} = 0.5 * ( 0.1 * 0.6 * 0.6 ) , \\ Memristor device {R}_{2 n} = 0.5 * ( 0.1 * 0.6 * 0.8 ) . \\ For the second processing unit : \\ Memristor device {R}_{11} = 0.5 * ( 0.1 * 0.4 * 0.6 ) , \\ Memristor device {R}_{21} = 0.5 * ( 0.1 * 0.4 * 0.8 ) , \\ Memristor device {R}_{12} = 0.5 * ( 0.1 * 0.8 * 0.6 ) , \\ Memristor device {R}_{22} = 0.5 * ( 0.1 * 0.8 * 0.8 ) , \\ … \\ Memristor device {R}_{1 n} = 0.5 * ( 0.1 * 0.2 * 0.6 ) , \\ Memristor device {R}_{2 n} = 0.5 * ( 0.1 * 0.2 * 0.8 ) .$$

FIG. 8A illustrates a schematic diagram of improving calculation robustness by an averaging method for a critical weight provided by at least one embodiment of the present disclosure.

As mentioned above, the reliability optimization method can be combined to improve the robustness of the computing apparatus. For example, the averaging strategy can be adopted for optimization of the critical weight device; and the re-refreshing strategy can be adopted for optimization of the critical weight device.

As illustrated in FIG. 8A, a left portion of the figure represents an original mapping and calculation relationship, and a dotted line box is a critical weight g₁₂ positioned based on the critical weight determination method. The average strategy method to improve calculation robustness is to make k copies of the critical weight (redundant backup), that is, to provide k memristor devices corresponding to the critical weights in the memristor array, these memristor devices have the same physical parameter and are set to the same conductance value, thereby an average effect can be configured to offset the fluctuation of the device. Here, k is a positive integer greater than 1. However, making the critical weights k copies will cause the calculation results to change. In order to ensure that the calculation results are unchanged, two methods can be used:

Method (1): changing the copied input to 1/k of the original input, while the conductance values of k memristor devices remain unchanged, as illustrated in the middle of FIG. 8A, an input x₂ becomes x₂/k.

Method (2): changing the conductance value of k memristor devices to 1/k of the original conductance value, while the input of each of k memristor devices remains unchanged, still x₂, as illustrated in the right side of FIG. 8A, the conductance g₁₂ becomes g₁₂/k.

FIG. 8B illustrates a schematic diagram of improving computing robustness by a re-refreshing strategy for a critical weight provided by at least one embodiment of the present disclosure.

As illustrated in FIG. 8B, the left side of the figure represents an original mapping and calculation relationship, and a dotted box contains critical weights g₁₂, g₂₁, and g₃ₙ positioned based on the critical weight determination method. As illustrated in a right portion of FIG. 8B, by re-refreshing the critical weights g₁₂, g₂₁, g₃ₙ, for example, according to a predetermined refreshing frequency, the conductance values of the memristor devices corresponding to the critical weights g₁₂, g₂₁, g₃ₙ, etc. are updated, so that the conductance values of these memristor devices remain stable, thereby restoring an accuracy of the computing apparatus and improving the robustness of the system.

It should be noted that in the embodiments of the present disclosure, the calculation robustness can be improved only by adopting the average strategy method illustrated in FIG. 8A, or only by adopting the re-refreshing method illustrated in FIG. 8B, or by both of the method illustrated in FIG. 8A and the method illustrated in FIG. 8B to improve computing robustness.

FIG. 9 illustrates a processing unit structure for determining critical weights and improving system robustness provided by at least one embodiment of the present disclosure.

Compared with the processing unit of the computing apparatus illustrated in FIG. 2, a structure of the processing unit illustrated in FIG. 9 has added one or more of the following four functional modules from the first portion to the fourth portion.

The first portion is a redundant memristor array and a redundant input module, which are configured to implement the averaging strategy of critical weights. The redundant memristor array is obtained by copying the selected critical devices, a row of the redundant memristor array is connected to a redundant input module, and a row of the computing memristor array is connected to a normal input module. As illustrated in FIG. 9, a column of the redundant memristor array correspond to a column of the computing memristor array one-to-one to share the same bit line, and a row of the redundant memristor array is parallel to a row of the computing memristor array.

The second portion is a critical weight control unit, which is configured to at least partially select and process the critical weight device.

The third portion is a deviation computing and processing unit, for example, it can receive a first actual output value of each column of the memristor array during the operation and the corresponding first ideal value, and obtain a first deviation between the first actual output value and the first ideal value, or it can receive a second actual output value of each neuron in a neural unit layer of the neural network where the memristor array is located, and obtain a second deviation between the second actual output value and the second ideal value, which is configured to obtain the on-chip calculation deviation.

The fourth portion is a refreshing control unit, which is configured to implement a remapping of the critical weight device in the computing memristor array.

The same portions as the processing unit of the computing apparatus illustrated in FIG. 2 can be described in detail with reference to FIG. 2 and will not be described again here.

It should be noted that the processing unit illustrated in FIG. 9 is only exemplary and does not limit the present disclosure, the processing unit can select the above first portion to the fourth portion according to the actual situation, or modify the first portion to the fourth portion.

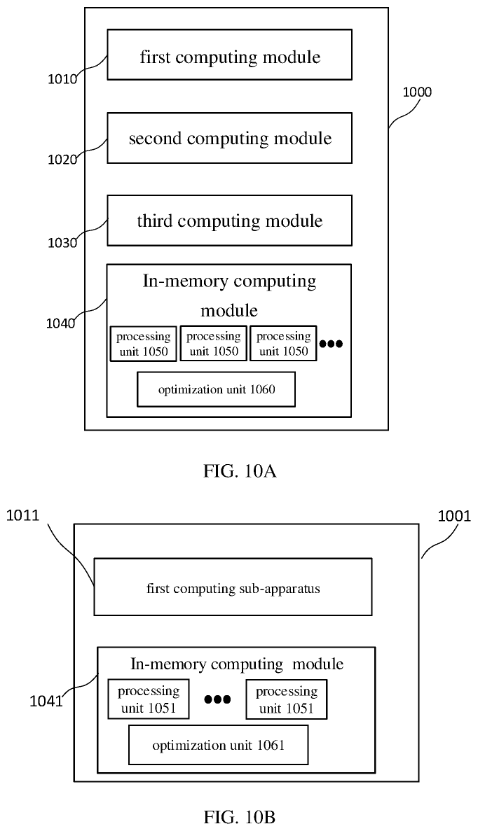

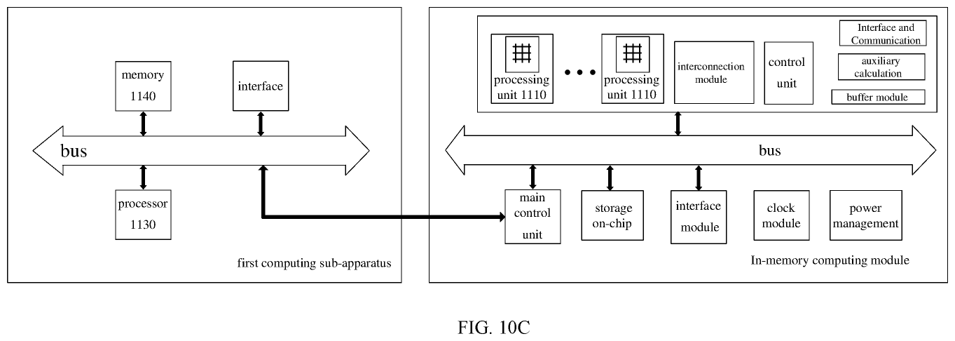

FIG. 10A illustrates a schematic diagram of a computing apparatus provided by at least one embodiment of the present disclosure.

As illustrated in FIG. 10A, the computing apparatus 1000 includes: a first computing module 1010, a second computing module 1020, a third computing module 1030 and an in-memory computing module 1040, wherein the in-memory computing module includes at least one processing unit 1050 (for example, first processing unit) and an optimization unit 1060. Each of the at least one processing unit 1050 includes a first computing memristor array, which includes a plurality of memristor devices arranged in an array. The processing unit 1050 may be, for example, the processing unit illustrated in FIG. 2 or FIG. 9 according to settings of other modules.

The computing apparatus can be configured to implement the above robustness processing method and perform a target robustness improvement on some critical memristor devices (critical weight devices), thereby achieving low cost and high robustness.

The first computing module 1010 is configured to, based on model parameters of a target algorithm model, obtain a mapping relationship between the model parameters and the first computing memristor array, and based on an influence factor that determines a critical weight device, determine a way to obtain a weight criticality of the plurality of memristor devices from the influence factor. For example, the first computing module 1010 may perform steps S501 and S502 described in FIG. 5A or steps S511 and S512 described in FIG. 5B.

The second computing module 1020 is configured to obtain an input set of the algorithm model, and determine a criticality value for each of the plurality of memristor devices according to the way to obtain the weight criticality. The second computing module 1020 may, for example, perform at least part of the operations in step S503 described in FIG. 5A or steps S513 and S514 described in FIG. 5B.

The third computing module 1030 is configured to determine a critical weight device among the plurality of memristor devices according to the criticality value for each of the plurality of memristor devices. The third computing module 1030 may, for example, perform step S504 described in FIG. 5A or step S515 described in FIG. 5B.

The optimization unit 1060 is configured to perform optimization processing on the first computing memristor array included in the processing unit 1050 based on the critical weight device. The optimization unit 1060 may, for example, perform step S505 described in FIG. 5A or step S516 described in FIG. 5B. For example, the optimization unit 1060 may be implemented as the first portion and/or the fourth portion illustrated in FIG. 9.

FIG. 10B illustrates a schematic diagram of another computing apparatus provided by at least one embodiment of the present disclosure.

As illustrated in FIG. 10B, the computing apparatus 1101 includes a first computing sub-apparatus 1011 and an in-memory computing module 1041.

The in-memory computing module 1041 includes at least one processing unit 1051 (for example, a first processing unit) and an optimization unit 1061. Each of the at least one processing unit 1051 includes a first computing memristor array, which includes a plurality of memristor devices arranged in an array. The processing unit 1051 may be, for example, the processing unit illustrated in FIG. 2 or FIG. 9 according to the settings of other modules.

The first computing sub-apparatus 1011 includes a processor and a memory, wherein the memory stores a computer executable program, and the computer executable program, when executed by the processor, is configured to implement the following method:

Based on model parameters of a target algorithm model, obtaining a mapping relationship between the model parameters and the first computing memristor array; based on an influence factor that determines a critical weight device, determining a way to obtain a weight criticality of the plurality of memristor devices from the influence factor; obtaining an input set of the algorithm model, and determine a criticality value for each of the plurality of memristor devices according to the way; determining a critical weight device among the plurality of memristor devices according to the criticality value for each of the plurality of memristor devices; and based on the critical weight device, providing an instruction for performing optimization processing on the first processing unit.

The optimization unit 1061 is configured to, based on the critical weight device, perform an optimization processing on the first computing memristor array included in the first processing units 1051 according to the instruction of the first computing sub-apparatus 1011. The optimization unit 1061 may, for example, perform step S505 described in FIG. 5A or step S516 described in FIG. 5B. For example, the optimization unit may be implemented as the first portion and/or the fourth portion illustrated in FIG. 9.

For example, in this embodiment, the first computing sub-apparatus 1011 and the in-memory computing module 1041 can be prepared in different chips and then communicate through a bus or other means, for example, they are disposed on the same circuit board and communicate through lines on the circuit board; alternatively, the first computing sub-apparatus 1011 and the in-memory computing module 1041 can be prepared in the same chip as different modules of the chip, so that they can communicate through lines inside the chip.

FIG. 10C illustrates a schematic diagram of another computing apparatus provided by at least one embodiment of the present disclosure, and this embodiment is an example of FIG. 10B.

As illustrated in FIG. 10C, the computing apparatus includes a first computing sub-apparatus and an in-memory computing module. It should be noted that the computing apparatus illustrated in FIG. 10C is only exemplary, and a specific implementation is not unique, the circuit modules, etc. included can be increased or decreased according to actual needs. For example, a main control unit of the in-memory computing module can be coupled to the bus of the first computing sub-apparatus to implement communication with the first computing sub-apparatus. The in-memory computing module includes at least one processing unit 1110 and an optimization unit, each of the at least one processing unit 1110 includes a computing memristor array, the computing memristor array includes a plurality of memristor devices arranged in an array. The optimization unit is configured to, based on the critical weight device, perform an optimization processing on the processing unit 1110 according to the instruction of the first computing sub-apparatus. For example, the optimization unit may be implemented as the first portion and/or the fourth portion arranged in the processing unit as illustrated in FIG. 9, or the optimization unit can be arranged outside the processing unit, for example, and can perform the optimization operation on the memristor array within the processing unit. The first computing sub-apparatus includes a processor 1130 (for example, a central processing unit) and a memory 1140, where the memory stores a computer executable program that can be run by the processor 1130 to perform the above robustness processing method.

For example, in the case where the weight criticality determination method that is independent of hardware is adopted, steps S501 to S504 illustrated in FIG. 5A can be implemented on the first computing sub-apparatus (for example, integrated into a compiler, that is, integrated into a portion of the computer executable program corresponding to compilation), step S505 requires a target optimization and improvement of the in-memory computing module according to the critical weight device, which can be completed within the in-memory computing module.

For example, in the case where the weight criticality determination method that is relevant to hardware is adopted, steps S511, S512, and S515 illustrated in FIG. 5B can be implemented on the first computing sub-apparatus (for example, integrated into a compiler, that is, integrated into a portion of the computer executable program corresponding to compilation), the operations of steps S513 and S514 can be implemented in the in-memory computing module. As another example, some operations in step S514 (for example, storage of the ideal output value and a calculation of deviation, etc.) can also be implemented in the first calculation sub-apparatus, for example, can be implemented through the third portion illustrated in FIG. 9. Step S516 requires a target optimization and improvement of the integrated storage module based on the critical weight, which can be completed within the in-memory computing module.

The above processor may be, for example, a central processing unit, a graphics processor, etc., may be an architecture such as CISC, RISC, etc., and may perform various appropriate actions and processes according to the program stored in the memory. Specific examples of the above memory may include, but are not limited to: a magnetic disk, a hard disk, a random access memory (RAM), a read-only memory (ROM), an erasable programmable read-only memory (EPROM or a flash memory), a portable compact disk read-only memory (CD-ROM), an optical storage device, a magnetic storage device, or any suitable combination of the above. The embodiments of the present disclosure do not limit the specific type, structure, etc. of the processor and memory.

It should be noted that, for the sake of clarity and conciseness, the embodiments of the present disclosure do not provide all the constituent units of the computing apparatus, nor all the constituent units of the processing units included in the computing apparatus. In order to realize necessary functions of the computing apparatus and the processing unit included in the computing apparatus, those skilled in the art can provide and set other not-illustrated component units according to specific needs, and the embodiments of the present disclosure do not limit this.

Regarding technical effects of the computing apparatus and the in-memory computing module, the processing unit, etc. included in the computing apparatus in different embodiments, please refer to the technical effects of the robustness processing method of the computing apparatus provided in the embodiments of the present disclosure, which will not be described again here.

It is to be noted that:
(1) The drawings of the embodiment of this disclosure only relate to the structure related to the embodiment of this disclosure, and other structures can refer to the general design.
(2) In the case of no conflict, the embodiments of the present disclosure and the features in the embodiments can be combined with each other to obtain a new embodiment.

The above is only an exemplary embodiment of the present disclosure, and is not used to limit the protection scope of the present disclosure, which is determined by the appended claims.

1. A robustness processing method of a computing apparatus, the computing apparatus comprising at least one processing unit, the at least one processing unit comprising a first processing unit, the first processing unit comprising a first computing memristor array, the first computing memristor array comprising a plurality of memristor devices arranged in an array,
wherein the method comprises:
based on model parameters of a target algorithm model, obtaining a mapping relationship between the model parameters and the first computing memristor array;
based on an influence factor that determines a critical weight device, determining a way to obtain a weight criticality of the plurality of memristor devices from the influence factor;
obtaining an input set of the algorithm model, and determining a criticality value for each of the plurality of memristor devices according to the way;
determining a critical weight device among the plurality of memristor devices according to the criticality value for each of the plurality of memristor devices; and
based on the critical weight device, performing an optimization processing on the first processing unit.

2. The method according to claim 1, wherein a critical weight comprises a first critical weight that is independent of a hardware of the first processing unit, and the influence factor that determines the critical weight device comprises at least one first sub-influence factor,
based on the influence factor that determines the critical weight device, determining a way to obtain a first weight criticality of the plurality of memristor devices from the influence factor, comprising:
based on the at least one first sub-influence factor, determining a way to obtain a first weight criticality for each of the plurality of memristor devices from the first sub-influence factor.

3. The method according to claim 2, wherein the at least one first sub-influence factor comprises an importance factor for each of the plurality of memristor devices and/or a risk factor that affects a reliability of the first processing unit.

4. The method according to claim 3, wherein the importance factor for each of the plurality of memristor devices comprises a conductance value or a received input value for each of the plurality of memristor devices; the risk factor that affects the reliability of the first processing unit comprises a hardware feature or an algorithm task feature of the first processing unit.

5. The method according to claim 3, wherein based on the at least one first sub-influence factor, determining a way to obtain a first weight criticality for each of the plurality of memristor devices from the first sub-influence factor, comprising:
through formula (1):
$$f {1}_{i} = {\sum }_{i} [ {r}_{p} \cdot ( α \cdot g \cdot {x}_{i} + β \cdot r ( g ) ) ] \qquad ( 1 )$$
calculating a first weight criticality value of any memristor device R in the first computing memristor array for the input value xi, wherein
f1ᵢ is the first weight criticality value of the memristor device R for the input value xᵢ,
g is a conductance value of the memristor device R,
p refers to the first processing unit or the first computing memristor array,
xᵢ is an input value for the memristor device R in the i-th operation,
r(g) is a reliability risk coefficient in the case where the conductance value is g,
rₚ is a model risk of the first processing unit or the first computing memristor array,
α is a hyperparameter corresponding to the importance factor,
β is a hyperparameter corresponding to the risk factor.

6. The method according to claim 5, wherein based on the at least one first sub-influence factor, determining a way to obtain a first weight criticality for each of the plurality of memristor devices from the first sub-influence factor, further comprising:
for the memristor device R, accumulating the first weight criticality values of all the input values in a first input set to obtain a final first weight criticality value of the memristor device R.

7. The method according to claim 6, wherein based on the at least one first sub-influence factor, determining a way to obtain a first weight criticality for each of the plurality of memristor devices from the first sub-influence factor, further comprising:
obtaining the first input set by uniformly sampling a training set for the algorithm model.

8. The method according to claim 1, wherein a critical weight comprises a second critical weight related to the first processing unit, and the influence factor that determines the critical weight device comprises at least one second sub-influence factor,
based on the influence factor that determines the critical weight device, determining a way to obtain a second weight criticality of the plurality of memristor devices from the influence factor, comprising:
based on the at least one second sub-influence factor, determining a way to obtain a second weight criticality for each of the plurality of memristor devices from the second sub-influence factor.

9. The method according to claim 8, wherein the at least one second sub-influence factor comprises: an on-chip calculation deviation, an algorithm model risk coefficient, or input values for the plurality of memristor devices.

10. The method according to claim 9, wherein the on-chip calculation deviation comprises:
a first deviation between a first actual output value of each column of the first computing memristor array and a corresponding first ideal value, and/or
a second deviation between a second actual output value of each neuron in a neural unit layer of the neural network where the first computing memristor array is located and a corresponding second ideal value.

11. The method according to claim 10, wherein based on the at least one second sub-influence factor, determining a way to obtain a second weight criticality for each of the plurality of memristor devices from the second sub-influence factor, comprising:
through formula (2):
$$f {2}_{i} = {\sum }_{i} {r}_{p} \cdot ( α \cdot {x}_{i} \cdot {δ}_{i} ) \qquad ( 2 )$$
calculating a second weight criticality value of any memristor device R in the first computing memristor array for the input value xi, wherein
f2ᵢ is the second weight criticality value of the memristor device R for the input value xᵢ,
xᵢ is an input value for the memristor device R in the i-th operation,
δᵢ is a first deviation or a second deviation of a column or a neuron where the memristor device R is located in the i-th operation,
rₚ is a model risk coefficient of the first processing unit or the first computing memristor array,
α is an importance coefficient and is a hyperparameter.

12-13. (canceled)

14. The method according to claim 11, wherein based on the at least one second sub-influence factor, determining a way to obtain a second weight criticality for each of the plurality of memristor devices from the second sub-influence factor, further comprising:
during a computing process, setting different weight coefficients for different input values.

15. The method according to claim 1, wherein based on the critical weight device, optimizing the first processing unit, comprising:
optimizing the critical weight devices by using an averaging strategy; and/or
optimizing the critical weight devices by using a re-refreshing strategy.

16. The method according to claim 1, wherein determining a critical weight device among the plurality of memristor devices based on the criticality value for each of the plurality of memristor devices, comprises:
among the plurality of memristor devices, selecting a memristor device with a criticality value greater than a threshold corresponding to the first processing unit as the critical weight device; or,
among the plurality of memristor devices, selecting a device whose criticality value is within a first percentage of criticality values being sorted by size of the plurality of memristor devices as the critical weight device; or
in each column of the plurality of memristor devices, selecting a device whose criticality value is within a second percentage of criticality values being sorted by size of the memristor device in the each column as the critical weight device.

17. (canceled)

18. The method according to claim 1, wherein obtaining a mapping relationship between the model parameters and the first computing memristor array, comprises:
obtaining the model parameters through compiler deployment and division, and mapping a portion of the model parameters corresponding to the first computing memristor array to a plurality of memristor devices of the first computing memristor array.

19. A computing apparatus, comprising: a first computing module, a second computing module, a third computing module and an in-memory computing module,
wherein the in-memory computing module comprises at least one processing unit and an optimization unit, the at least one processing unit comprises a first processing unit, the first processing unit comprises a first computing memristor array, and the first computing memristor array comprises a plurality of memristor devices arranged in an array;
the first computing module is configured to, based on model parameters of a target algorithm model, obtain a mapping relationship between the model parameters and the first computing memristor array, and based on an influence factor that determines a critical weight device, determine a way to obtain a weight criticality of the plurality of memristor devices from the influence factor;
the second computing module is configured to, obtain an input set of the algorithm model, and determine a criticality value for each of the plurality of memristor devices according to the way;
the third computing module is configured to determine a critical weight device among the plurality of memristor devices according to the criticality value for each of the plurality of memristor devices;
the optimization unit is configured to perform optimization processing on the first processing unit based on the critical weight device.

20. A computing apparatus, comprising: a first computing sub-apparatus and an in-memory computing module,
wherein the in-memory computing module comprises at least one processing unit and an optimization unit, the at least one processing unit comprises a first processing unit, the first processing unit comprises a first computing memristor array, and the first computing memristor array comprises a plurality of memristor devices arranged in an array;
the first computing sub-apparatus comprises:
a processor and a memory, wherein the memory stores a computer executable program, and the computer executable program, when executed by the processor, is configured to implement the following method:
based on model parameters of a target algorithm model, obtaining a mapping relationship between the model parameters and the first computing memristor array;
based on an influence factor that determines a critical weight device, determining a way to obtain a weight criticality of the plurality of memristor devices from the influence factor;
obtaining an input set of the algorithm model, and determine a criticality value for each of the plurality of memristor devices according to the way;
determining a critical weight device among the plurality of memristor devices according to the criticality value for each of the plurality of memristor devices; and
based on the critical weight device, providing an instruction for performing optimization processing on the first processing unit;
wherein the optimization unit is configured to, based on the critical weight device, perform an optimization processing on the first processing unit according to the instruction.

21. The computing apparatus according to claim 19, wherein the optimization unit comprises a redundant weight processing unit, which comprises a first redundant memristor array,
columns of the first redundant memristor array are in one-to-one correspondence with columns of the first computing memristor array to share the same bit line,
rows of the first redundant memristor array are parallel to rows of the first computing memristor array.

22. (canceled)

23. The computing apparatus according to claim 19, wherein the in-memory computing module further comprises a critical weight control unit, which is configured to select and process the critical weight device.

24. The computing apparatus according to claim 19, wherein the in-memory computing module further comprises a deviation computing and processing unit, and the deviation computing and processing unit is configured to,
receive a first actual output value of each column of the first computing memristor array during an operation process and receive a corresponding first ideal value, and obtain a first deviation between the first actual output value and the first ideal value, and/or
receive a second actual output value of each neuron in a neural unit layer of the neural network where the first computing memristor array is located and a corresponding second ideal value, and obtain a second deviation between the second actual output value and the second ideal value.
